(19) United States
(12) Patent Application Publication
(10) Pub. No.: US 2024/0405511 A1
(43) Pub. Date: Dec. 5, 2024

(54) EDGE-EMITTING SEMICONDUCTOR LASER DIODES AND METHOD FOR PRODUCING A PLURALITY OF EDGE-EMITTING SEMICONDUCTOR LASER DIODES

(71) Applicant: ams-OSRAM International GmbH, Regensburg (DE)

(72) Inventors: Sven GERHARD, Alteglofsheim (DE); Alfred LELL, Maxhütte-Haidhof (DE); Christoph EICHLER, Donaustauf (DE)

(73) Assignee: ams-OSRAM International GmbH, Regensburg (DE)

(21) Appl. No.: 18/695,769

(22) PCT Filed: Sep. 6, 2022
(86) PCT No.: PCT/EP2022/074722

§ 371 Date: Mar. 26, 2024

(30) Foreign Application Priority Data
Sep. 28, 2021 (DE) 102021125119.2

(51) Int. Cl. H01S 5/10; H01S 5/22; H01S 5/323; H01S 5/40

(52) U.S. Cl. CPC H01S 5/1082; H01S 5/22; H01S 5/32341; H01S 5/4031

(57) ABSTRACT

The invention relates to an edge-emitting semiconductor laser diode, including the following features: an epitaxial semiconductor layer stack including an active one, in which during operation electromagnetic radiation is generated, wherein the epitaxial semiconductor layer stack has at least one facet which laterally delimits the epitaxial semiconductor layer stack, and the facet has at least one first partial surface and at least one second partial surface which have reflectivities differing from one another for the electromagnetic radiation generated in the active zone. The invention also relates to methods for producing a plurality of edge-emitting semiconductor laser diodes.

### CROSS-REFERENCE TO RELATED APPLICATIONS

The present application is a national stage entry from International Application No. PCT/EP2022/074722, filed on Sep. 6, 2022, published as International Publication No. WO 2023/052053 A1 on Apr. 6, 2023, and claims priority to German Patent Application No. 10 2021 125 119.2, filed Sep. 28, 2021, the disclosures of all of which are hereby incorporated by reference in their entireties.

### FIELD

An edge-emitting semiconductor laser diode and methods of manufacturing a plurality of edge-emitting semiconductor laser diodes are disclosed.

### BACKGROUND

An improved edge-emitting semiconductor laser diode is to be provided. In particular, the semiconductor laser diode should have a beam quality that is as homogeneous as possible, increased efficiency and high reliability. Furthermore, simplified methods for manufacturing such a semiconductor laser diode, in particular at wafer level, are to be provided.

These tasks are solved by an edge-emitting semiconductor laser diode with the features of patent claim 1 and by the methods with the steps of patent claims 12 and 18.

Advantageous embodiments and developments of the semiconductor laser diode and the methods are given in the respective dependent claims.

### SUMMARY

According to an embodiment, the edge-emitting semiconductor laser diode has an epitaxial semiconductor layer stack with an active zone in which electromagnetic radiation is generated during operation. In particular, the semiconductor layer stack has a plurality of semiconductor layers grown epitaxially on top of one another or is formed from a plurality of semiconductor layers grown epitaxially on top of one another. The epitaxial semiconductor layer stack has a stacking direction on which the epitaxially grown semiconductor layers of the epitaxial semiconductor layer stack are perpendicular.

According to a further embodiment of the semiconductor laser diode, the semiconductor layer stack has at least one facet that laterally delimits the epitaxial semiconductor layer stack. In particular, the facet is part of the epitaxial semiconductor layer stack. In particular, the facet forms all or part of a side surface of the epitaxial semiconductor layer stack. In other words, the facet is formed, in particular, from the semiconductor material of the semiconductor layer stack.

According to a further embodiment of the semiconductor laser diode, the semiconductor layer stack has a further facet. The two facets are preferably opposite to each other and form all or part of the side surfaces of the epitaxial semiconductor layer stack. All embodiments and features described here in connection with one facet can also be formed on both facets.

According to a further embodiment of the semiconductor laser diode, the facet has at least a first partial surface and at least a second partial surface which have different reflectivities from each other for the electromagnetic radiation generated in the active zone.

According to a preferred embodiment, the semiconductor laser diode has an epitaxial semiconductor layer stack comprising an active zone in which electromagnetic radiation is generated during operation. Here, the semiconductor layer stack has at least one facet which laterally delimits the epitaxial semiconductor layer stack, and the facet has at least a first partial surface and at least a second partial surface which have different reflectivities from one another for the electromagnetic radiation generated in the active zone.

According to a further embodiment of the semiconductor laser diode, the facets form a resonator for the electromagnetic radiation generated in the active zone. A standing wave of electromagnetic radiation generally forms in the resonator during operation of the semiconductor laser diode. The active zone serves as a laser medium in which a population inversion is generated within the resonator during operation. Due to the population inversion, the electromagnetic radiation is generated in the active zone by stimulated emission, which leads to the formation of electromagnetic laser radiation in the resonator. Due to the generation of the electromagnetic laser radiation by stimulated emission, the electromagnetic laser radiation usually has a very high coherence length, a very narrow emission spectrum and/or a high degree of polarization, in contrast to electromagnetic radiation generated by spontaneous emission.

According to an embodiment of the semiconductor laser diode, the electromagnetic laser radiation has different modes. In particular, the modes of the laser radiation differ in wavelength, phase and/or amplitude. Furthermore, electromagnetic laser radiation of different modes generally impinges on different partial surfaces of the facets forming the resonator.

If the facet has different partial surfaces with different reflectivities for the electromagnetic radiation generated in the active zone, different modes of the electromagnetic laser radiation in particular can be specifically influenced. Desired modes can be amplified by an increased reflectivity and undesired modes can be less amplified or attenuated by a reduced reflectivity. For example, a partial surface with a reduced reflectivity for the electromagnetic radiation of the active zone has a reflectivity of at most 17%.

According to a further embodiment of the edge-emitting semiconductor laser diode, the first partial surface has a greater reflectivity for the electromagnetic radiation of the active zone than the second partial surface. Furthermore, the first partial surface favors the amplification of a desired mode of the electromagnetic laser radiation in a resonator and the second partial surface favors the attenuation of an undesired mode of the electromagnetic laser radiation in the resonator. In particular, the first partial surface amplifies a desired mode of the electromagnetic laser radiation in the resonator, and the second partial surface at least attenuates an undesired mode of the electromagnetic laser radiation in the resonator. Preferably, the second partial surface extinguishes the undesired mode of the electromagnetic laser radiation in the resonator. Preferably, no undesired mode emerges from the resonator.

In the present edge-emitting semiconductor laser diode, it is also possible that several different partial surfaces are arranged on the facet, which have at least partially different reflectivities from one another for the electromagnetic radiation generated in the active zone. All the features and embodiments described above in connection with the first partial surface and the second partial surface can also be formed on all or some of the other partial surfaces.

According to a further embodiment of the edge-emitting semiconductor laser diode, one or more reflective coating layers are applied to the facet, preferably over the entire surface. In particular, the reflective coating layers at least partially reflect the electromagnetic radiation generated in the active zone.

According to a further embodiment of the edge-emitting semiconductor laser diode, the electromagnetic radiation generated in the active zone is formed in a resonator into electromagnetic laser radiation comprising several modes. In particular, the resonator is formed by two opposing facets of the semiconductor layer stack.

The present edge-emitting semiconductor laser diode has the advantage that only desired modes of the electromagnetic laser radiation can be amplified by the first partial surface and the second partial surface, which have different reflectivities for the electromagnetic radiation generated in the active zone, while undesired modes of the electromagnetic laser radiation are less amplified or attenuated when impinging on a partial surface with lower reflectivity. In particular, a locally high intensity of electromagnetic laser radiation on a facet (filamentation) can at least be reduced. Thus, a positive effect on efficiency, reliability and beam quality can be achieved.

According to a further embodiment of the edge-emitting semiconductor laser diode, the first partial surface has a greater reflectivity than the second partial surface and the first partial surface amplifies one mode of the laser radiation during operation more than the second partial surface amplifies another mode of the laser radiation.

According to a further embodiment of the edge-emitting semiconductor laser diode, the first partial surface and the second partial surface have different roughnesses. In the present case, roughness refers in particular to the geometric mean roughness value Ra. The geometric mean roughness value specifies the mean distance of a measuring point on a surface, whose roughness is to be determined, from a center line. For example, to determine the geometric mean roughness value, the respective partial surface is scanned on a measuring section and all height and depth differences are recorded as a roughness curve. After determining the integral of the roughness profile on the measurement section, the result is divided by the length of the measurement section. For example, a difference between the roughness of the first partial surface and the roughness of the second partial surface has a value ARa between 5 nanometers and 20 nanometers, inclusive.

The roughness of the respective partial surface generally determines its reflectivity. A partial surface with a high roughness generally has a lower reflectivity for electromagnetic radiation from the active zone than a partial surface with a low roughness. In other words, the reflectivity of the partial surfaces can be specifically adjusted via their roughness.

According to a further embodiment of the edge-emitting semiconductor laser diode, the first partial surface is formed tilted by a first vertical angle relative to a vertical main surface of the epitaxial semiconductor layer stack. Here, the vertical main surface is perpendicular to a longitudinal direction that runs from one facet to the other facet. The longitudinal direction thus runs parallel to an optical axis of the resonator. Furthermore, the longitudinal direction is perpendicular to the stacking direction of the epitaxial semiconductor layer stack. In particular, the first partial surface and the second partial surface have reflectivities different from each other for the electromagnetic radiation generated in the active zone in the longitudinal direction.

According to a further embodiment of the semiconductor laser diode, the second partial surface is tilted by a second vertical angle relative to the vertical main surface of the epitaxial semiconductor layer stack.

An intersection line of the partial surface tilted by the respective vertical angle with the vertical main surface is perpendicular to the stacking direction and to the longitudinal direction.

If the first partial surface and the second partial surface are each formed tilted by a vertical angle relative to the vertical main surface of the epitaxial semiconductor layer stack, the vertical angles are in particular different from one another. For example, one vertical angle has a value not greater than +/−6°, preferably not greater than +/−2°, while the other angle has a value of at least +/−8°, preferably at least +/−10°. In particular, it is also possible that only one of the two partial surfaces is tilted with respect to the vertical main surface of the epitaxial semiconductor layer stack, while the other partial surface runs parallel to the vertical main surface.

According to a further embodiment of the semiconductor laser diode, the first partial surface is tilted by a first vertical angle and the second partial surface is tilted by a second vertical angle, with the first vertical angle and the second vertical angle being different from each other. Preferably, the partial surface with the larger vertical angle has a higher roughness than the partial surface with the smaller vertical angle.

According to a further embodiment of the edge-emitting semiconductor laser diode, the first partial surface is tilted by a first lateral angle relative to the vertical main surface of the epitaxial semiconductor layer stack and/or the second partial surface is tilted by a second lateral angle relative to the vertical main surface of the epitaxial semiconductor layer stack. An intersection line of the partial surface tilted by the respective lateral angle with the vertical main surface runs parallel to the stacking direction.

If the semiconductor laser diode has several partial surfaces that are tilted at different lateral angles to the vertical main surface of the epitaxial semiconductor layer stack, cut-outs and protrusions can be formed in the facets. In particular, several partial surfaces with different lateral angles are directly adjacent to each other.

According to a further embodiment of the semiconductor laser diode, the facet has a radiation exit region. In particular, the facet emits electromagnetic laser radiation generated within the resonator from the radiation exit region. In other words, the entire surface of the facet is generally not intended to emit electromagnetic laser radiation. Rather, the facet only emits electromagnetic laser radiation from the radiation exit region during operation. As a rule, only a single facet of the semiconductor laser diode has a radiation exit region. The emission of electromagnetic laser radiation from the radiation exit region is usually generated by one or more reflective coating layers on the facet, which are partially transparent to the electromagnetic laser radiation. If the facet has cut-outs and protrusions, these are particularly preferably formed in the radiation exit region.

Particularly preferably, the first partial surface covers the radiation exit region of the facet and the first partial surface has a greater reflectivity for the electromagnetic radiation of the active zone than the second partial surface. Particularly preferably, the second partial surface with a lower reflectivity for electromagnetic radiation, for example due to a greater roughness, does not cover the radiation exit region of the facet. Preferably, the first partial surface amplifies an impinging mode of the electromagnetic laser radiation while the second partial surface attenuates one or more modes of the electromagnetic laser radiation.

According to a further embodiment of the edge-emitting semiconductor laser diode, the first partial surface covers a radiation exit region of the facet and the first partial surface is arranged between two second partial surfaces which have a lower reflectivity for the electromagnetic radiation of the active zone than the first partial surface. Preferably, the first partial surface amplifies an impinging mode of the electromagnetic laser radiation while the second partial surfaces attenuate one or more modes of the electromagnetic laser radiation.

According to a further embodiment, the semiconductor laser diode has a ridge waveguide. In particular, in the case of a semiconductor laser diode with a comparatively wide ridge waveguide, the electromagnetic laser radiation generated in the resonator generally has several modes. Therefore, a selection of the modes by a facet with different reflectivities is particularly useful for an edge-emitting semiconductor laser diode with a wide ridge waveguide. For example, the ridge waveguide has a width of between 1 micrometer and 100 micrometers, preferably between 2 micrometers and 50 micrometers, inclusive.

The ridge waveguide is generally intended to guide the electromagnetic laser radiation within the epitaxial semiconductor layer stack. As a rule, the radiation exit region of the facet is therefore also arranged along the stacking direction below the ridge waveguide.

According to a further embodiment, the edge-emitting semiconductor laser diode is an index-guided semiconductor laser diode that is free of a ridge waveguide. In the index-guided semiconductor laser diode, the electromagnetic laser radiation is guided in the epitaxial semiconductor layer stack by a current impression into the active zone, the current injection which is made by two electrical contacts on a first main surface and a second main surface opposite the first main surface.

According to a further embodiment of the semiconductor laser diode, the facet has further partial surfaces with at least partially different reflectivities for the electromagnetic radiation generated in the active zone.

According to a further embodiment of the semiconductor laser diode, the facet has a plurality of partial surfaces, which are each formed tilted by a lateral angle relative to the vertical main surface of the epitaxial semiconductor layer stack and form at least one cut-out and/or protrusion in the facet. The cut-out and/or the protrusion has, for example, a polygonal, rectangular, triangular, round or oval cross-sectional area in plan view of the main surface of the semiconductor laser diode.

The edge-emitting semiconductor laser diode is particularly configured for the use in an array with at least two edge-emitting semiconductor laser diodes. Features and embodiments, which are disclosed here only in connection with the semiconductor laser diode, can also be formed in the array and vice versa.

In particular, the semiconductor laser diodes of an array can be designed differently from one another or in the same way. For example, the semiconductor laser diodes of an array emit electromagnetic laser radiation that is at least partially different from one another. In particular, the electromagnetic laser radiation of the semiconductor laser diodes can have different wavelengths.

A plurality of edge-emitting semiconductor laser diodes can be manufactured using the methods described below. Features and embodiments, which are described here only in connection with the edge-emitting semiconductor laser diode, can also be formed in the method and vice versa.

According to an embodiment of the method of manufacturing a plurality of edge-emitting semiconductor laser diodes, an epitaxial semiconductor layer sequence is provided with an active region that generates electromagnetic radiation during operation.

According to a further embodiment of the method, one or more trenches are generated in the epitaxial semiconductor layer sequence. In particular, a side surface of a trench at least partially forms a facet of a finished semiconductor laser diode.

According to a further embodiment of the method, at least a first partial surface and at least a second partial surface are generated on the side surface of the trench, wherein the first partial surface and the second partial surface have different reflectivities from each other for the electromagnetic radiation generated in the active region.

In particular, a method of manufacturing a plurality of edge-emitting semiconductor laser diodes comprises the following steps:
providing an epitaxial semiconductor layer sequence with an active region that generates electromagnetic radiation during operation,
generating one or more trenches in the epitaxial semiconductor layer sequence,
generating at least a first partial surface and at least a second partial surface on a side surface of the trench, wherein the first partial surface and the second partial surface have different reflectivities from each other for the electromagnetic radiation generated in the active region.

Preferably, the specified steps are carried out in the specified order.

The method of manufacturing a plurality of edge-emitting semiconductor laser diodes is preferably carried out at wafer level. This means that the epitaxial semiconductor layer sequence is part of a wafer and the plurality of semiconductor laser diodes are produced simultaneously. This simplifies the manufacturing process.

At the end of the method, the edge-emitting semiconductor laser diodes are singulated, for example by scribing and breaking, stealth dicing or laser separation of the wafer. In particular, the trenches in the epitaxial semiconductor layer sequence provide separation lines along which the semiconductor laser diodes are singulated.

The edge-emitting semiconductor laser diodes with the semiconductor layer stacks and the active zone are created during singulation. The epitaxial semiconductor layer stacks of the various edge-emitting semiconductor laser diodes are part of the active semiconductor layer sequence at wafer level and the active zones are part of the active region at wafer level. Features and embodiments described herein in connection with the epitaxial semiconductor layer stack and the active zone may consequently also be formed in the epitaxial semiconductor layer sequence and the active region and vice versa.

In particular, the epitaxial semiconductor layer sequence, as well as the epitaxial semiconductor layer stacks, has a stacking direction on which the epitaxially grown semiconductor layers of the epitaxial semiconductor layer sequence are perpendicular. A vertical main surface of the epitaxial semiconductor layer sequence is perpendicular to a longitudinal direction extending along a main extension direction of the epitaxial semiconductor layer sequence. Furthermore, the longitudinal direction is perpendicular to the stacking direction of the epitaxial semiconductor layer stack.

It should also be noted that, for the sake of simplicity, features and elements are often described here only in the singular, although a plurality of the features and elements are usually generated simultaneously. For example, several first and second partial surfaces of different reflectivity are generated on the side surfaces of the trenches.

According to a further embodiment of the method, the trenches are generated using a dry etching process so that the side surfaces of the trenches have a vertical angle tilted to the vertical main surface of the epitaxial semiconductor layer sequence. The dry etching method can be, for example, a plasma etching method or reactive ion etching (RIE).

According to a further embodiment of the method, the partial surface generated by the wet chemical method has a lower roughness than the other partial surface.

According to a further embodiment of the method, the first partial surface or the second partial surface are generated by a wet chemical method using a mask, wherein the first partial surface and the second partial surface have different roughnesses. In the wet chemical method, for example, one or more of the following materials may be used as the etching medium: KOH, TMAH (tetramethylammonium hydroxide), NH₃, NaOH. In particular, the partial surface that is wet chemically etched is smoothed so that it has a lower roughness after wet chemical etching than before wet chemical etching.

In this embodiment of the method, the trenches are preferably first generated using a dry etching process such as plasma etching, with the side surfaces of the trenches generally being formed tilted at a vertical angle to the vertical main surface of the epitaxial semiconductor layer sequence. In the dry etching process, a comparatively rough surface is usually formed.

In a next step, a mask that is resistant to the material of the subsequent wet chemical method is applied to the partial surface of the side surface of the trenches that is to have a higher roughness in the finished semiconductor laser diode. For example, the mask has a metal, an oxide, such as TaO and/or HfO, and/or a nitride, such as SiN.

After the mask has been applied, the exposed part of the side surface of the trenches is smoothed by the wet chemical method, so that a further partial surface is created which has a lower roughness than the partial surface covered by the mask. In addition, the wet chemical method preferably involves further material removal, so that the areas of the side surfaces of the trenches not covered by the mask are formed vertically and thus parallel to the vertical main surface of the epitaxial semiconductor layer sequence.

According to a further embodiment of the method, the trenches are generated with a dry etching method, such as plasma etching, using at least one mask, such that the first partial surface encloses a first vertical angle with the vertical main surface and/or the second partial surface encloses a second vertical angle with the vertical main surface. In this embodiment of the method, the first partial surface and the second partial surface with different vertical angles are generated simultaneously when generating the trenches. In particular, in this embodiment of the method, the mask is applied to a main surface of the epitaxial semiconductor layer sequence.

According to a further embodiment of the method, the trenches are generated with a dry etching method using at least one mask so that the first partial surface encloses a first lateral angle with the vertical main surface and/or the second partial surface encloses a second lateral angle with the vertical main surface. In this method, too, the first partial surface and the second partial surface are generated at the same time as the trenches are generated. In particular, also in this embodiment of the method, the mask is applied to the main surface of the semiconductor layer sequence.

According to a further embodiment of the method, the mask has at least two mask layers, which have different selectivities for the dry etching process. The two mask layers are generally formed differently from each other and cover different areas of the main surface of the epitaxial semiconductor layer sequence. Thus, a first partial surface and/or a second partial surface, which include different lateral and/or different vertical angles with the vertical main surface, can be generated simultaneously when the trenches are created.

According to a further embodiment of the method, partial surfaces that include different lateral angles and/or different vertical angles with the vertical main surface are treated with a further wet chemical method. As a rule, partial surfaces that include a larger vertical and/or lateral angle with the vertical main surface can be smoothed less well with a wet chemical method and thus have a greater roughness than partial surfaces that include a smaller angle with the vertical main surface. In particular, partial surfaces that include an angle of less than or equal to +/−6° with the vertical main surface can be smoothed comparatively well by a wet chemical method, while partial surfaces that include an angle greater than or equal to +/−8°, preferably +/−10° with the vertical main surface, can be smoothed comparatively poorly. After wet chemical smoothing, the partial surface that includes an angle less than or equal to +/−6° with the vertical main surface before wet chemical smoothing preferably includes an angle less than or equal to +/−2° with the vertical main surface. In other words, the vertical angle is generally reduced during wet chemical smoothing. In particular, the vertical angle of a partial surface of a finished semiconductor laser diode includes an angle less than or equal to +/−2° with the main vertical surface if the partial surface is to amplify a main mode of a laser radiation.

In the following, a further method of manufacturing a plurality of edge-emitting semiconductor laser diodes is described. Features and embodiments, which have been described in connection with the semiconductor laser diode can also be formed in the method and vice versa. Furthermore, features and embodiments described in connection with the method already described may also be formed in the method described below and vice versa.

According to an embodiment of the method of manufacturing a plurality of edge-emitting semiconductor laser diodes, an epitaxial semiconductor layer sequence is provided comprising an active region that generates electromagnetic radiation during operation.

According to a further embodiment of the method, a plurality of structural elements is generated in the epitaxial semiconductor layer sequence, wherein a side surface of a structural element at least partially forms a first partial surface of a facet of a finished semiconductor laser diode. For example, the structural elements are cut-outs in the epitaxial semiconductor layer sequence.

According to a further embodiment of the method, the semiconductor layer sequence is singulated to form a plurality of edge-emitting semiconductor laser diodes, so that at least a second partial surface of the facet of the finished semiconductor laser diode is formed. In other words, the second partial surface is generated when the semiconductor laser diodes are singulated. Here, the first partial surface and the second partial surface have different reflectivities for the electromagnetic radiation generated in the active region.

In particular, the method comprises the following steps:
providing an epitaxial semiconductor layer sequence with an active region that generates electromagnetic radiation during operation,
generating a plurality of structural elements in the epitaxial semiconductor layer sequence, wherein a side surface of a structural element at least partially forms a first partial surface of a facet of a finished semiconductor laser diode,
singulating the semiconductor layer sequence into a plurality of edge-emitting semiconductor laser diodes, so that at least a second partial surface of the facet of the finished semiconductor laser diode is formed, wherein
the first partial surface and the second partial surface have different reflectivities for the electromagnetic radiation generated in the active region.

These steps are preferably carried out in the order given.

According to a further embodiment of the method, the first partial surface has a greater roughness than the second partial surface.

The structural elements are generated, for example, by wet chemical etching in a main surface of the epitaxial semiconductor layer sequence, for example with one of the etching media already indicated. Furthermore, it is also possible for the structural elements to be generated in the main surface of the epitaxial semiconductor layer sequence by a dry etching process, for example plasma etching.

A dry etching process of the structural elements results in structural elements with side surfaces that generally form a vertical angle with the vertical main surface of the semiconductor layer sequence. Furthermore, the side surfaces usually have a comparatively high roughness if they are generated by the dry etching process.

According to a further embodiment of the method, the semiconductor laser diodes are singulated by scribing and breaking into the plurality of semiconductor laser diodes. Furthermore, the other methods for singulation already mentioned are also possible.

As a rule, the facets of the semiconductor layer stacks are completed by singulation.

The partial surface of the facet generated by scribing and breaking generally has a comparatively low roughness and further generally extends parallel to the vertical main surface of the epitaxial semiconductor layer stacks. In other words, the partial surface of the facet generated by the dry etching process of the structural elements generally has a higher roughness than the partial surface of the facet generated by scribing and breaking for singulation. Furthermore, the partial surface of the facet generated by the dry etching process of the structural elements in the semiconductor layer sequence generally has a vertical angle with the vertical main surface of the epitaxial semiconductor layer stacks, while the partial surface of the facet generated by scribing and breaking is generally parallel to the vertical main surface.

In the following, methods for manufacturing edge-emitting semiconductor laser diodes and edge-emitting semiconductor laser diodes are explained in more detail with reference to exemplary embodiments in connection with the figures.

### BRIEF DESCRIPTION OF THE DRAWINGS

The schematic sectional views of FIGS. 1 to 5 show different stages of a method of manufacturing a plurality of semiconductor laser diodes according to an exemplary embodiment.

FIG. 6 shows a schematic top view of a facet of an edge-emitting semiconductor laser diode according to an exemplary embodiment.

The schematic views of FIGS. 7 to 9 illustrate the directions in space and areas of the edge-emitting semiconductor laser diode in more detail.

The schematic sectional view of FIG. 10 shows a stage of a method of manufacturing a plurality of semiconductor laser diodes according to a further exemplary embodiment.

The schematic sectional view of FIG. 11 shows a stage of a method of manufacturing a plurality of semiconductor laser diodes according to a further exemplary embodiment.

The schematic top views of FIGS. 12 and 13 show different stages of a method of manufacturing a plurality of semiconductor laser diodes according to a further exemplary embodiment.

FIGS. 14 to 32 show schematic representations of edge-emitting semiconductor laser diodes according to various exemplary embodiments.

FIG. 33 shows an example of a scanning electron microscope image of a facet of a semiconductor laser diode.

FIGS. 34 to 36 show schematic views of edge-emitting semiconductor laser diodes according to further exemplary embodiments.

FIGS. 37 and 38 show schematic representations of an array with a plurality of edge-emitting semiconductor laser diodes according to an exemplary embodiment.

### DETAILED DESCRIPTION

Elements that are identical, similar or have the same effect are marked with the same references in the figures. The figures and the proportions of the elements shown in the figures are not to be regarded as true to scale. Rather, individual elements, in particular layer thicknesses, may be shown in exaggerated size for better visualization and/or understanding.

In the method according to the exemplary embodiment of FIGS. 1 to 5, an epitaxial semiconductor layer sequence 1 is first provided, which has an active region 2 that is suitable for generating electromagnetic radiation during operation (not shown). The epitaxial semiconductor layer sequence 1 is provided in the present case in the form of a wafer and has a main surface 3.

A plurality of trenches 4 is provided in the epitaxial semiconductor layer sequence 1. For reasons of clarity, FIG. 1 only shows a section of the epitaxial semiconductor layer sequence 1 with a single trench 4.

The trenches 4 are preferably formed in the same way. The trenches 4 are particularly preferably arranged parallel to one another in the epitaxial semiconductor layer sequence 1.

The trench 4 does not completely penetrate the epitaxial semiconductor layer sequence 1 in the present case, but breaks through the active region 2. In other words, the wafer is still designed to be completely continuous in the epitaxial semiconductor layer sequence 1 after the trenches 4 have been generated.

The trench 4 has two opposite side surfaces 5. In the present case, the trenches 4 in the epitaxial semiconductor layer sequence 1 are generated by a plasma etching process. In this process, the side surfaces 5 of the trenches 4 are formed oblique to a vertical main surface 6 of the epitaxial semiconductor layer sequence 1. In addition, the side surfaces 5 of the trenches 4 have a comparatively high roughness due to the plasma etching process.

In a next step, a mask 7 is applied to the side surfaces 5 of the trenches 4 (FIGS. 2 and 3). As the top view of the side surface 5 of the trench 4 of FIG. 3 shows, the mask 7 is only applied in places to the side surface 5 of the trench 4, so that an region 8 of the side surface 5 is freely accessible.

In the present case, protrusions are already arranged in the main surface 3 of the epitaxial semiconductor layer sequence 1, which serve as the ridge waveguides 9 in the finished semiconductor laser diodes. In particular, regions 8 of the side surfaces 5 are not covered by the mask 7, which are arranged below the ridge waveguide 9 as seen from the main surface 3.

The mask 7 can, for example, be generated using a structured photoresist mask and a subsequent lift-off method. Here, the material of the mask is first applied over the entire surface of a structured photoresist mask on the side surface 5 of the trench 44. The photoresist mask is then removed so that the inverse structure of the photoresist mask is transferred to the material of the mask. Furthermore, it is also possible to apply a structured photoresist mask to a mask layer applied over the entire surface of the side surface 5 of the trench 4 and to actively structure the mask layer, for example by means of an etching process.

In a next step, the side surfaces 5 of the trenches 4 are smoothed with a wet chemical method, for example using KOH, TMAH, NH₃, NaOH as the etching medium, whereby the regions 8 of the side surfaces 5 not covered by the mask 7 are simultaneously formed parallel to the vertical main surface 6 of the epitaxial semiconductor layer sequence 1 (FIG. 4). Thus, first partial surfaces 10 are formed on the side surfaces 5 of the trenches 4, which have a lower roughness than second partial surfaces 11. FIG. 5 shows a section through a partial surface with an increased roughness.

Finally, the semiconductor laser diodes are singulated along the trenches, for example by breaking, so that a plurality of edge-emitting semiconductor laser diodes are created.

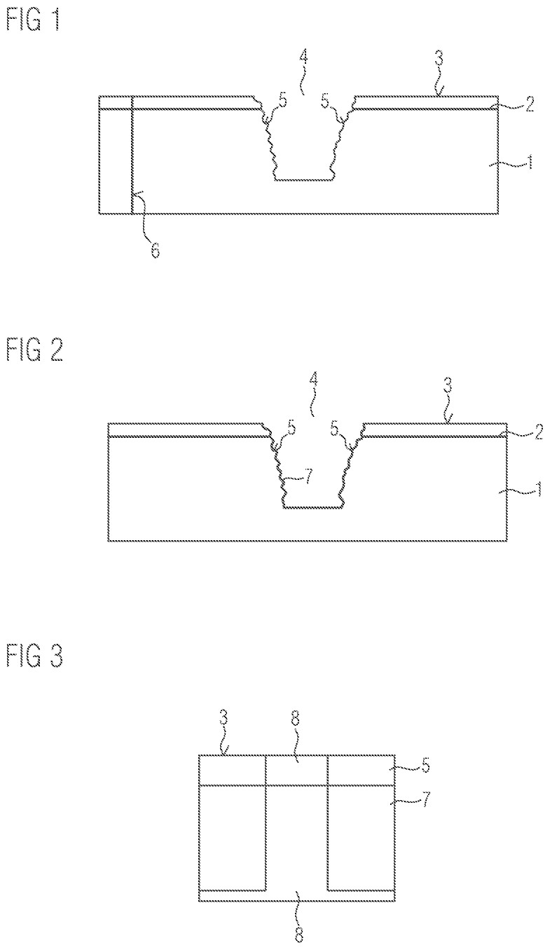

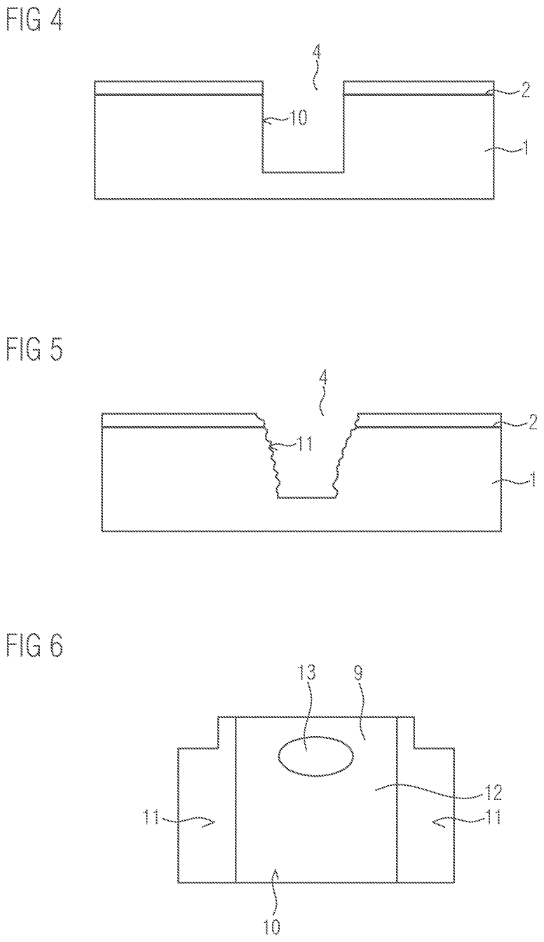

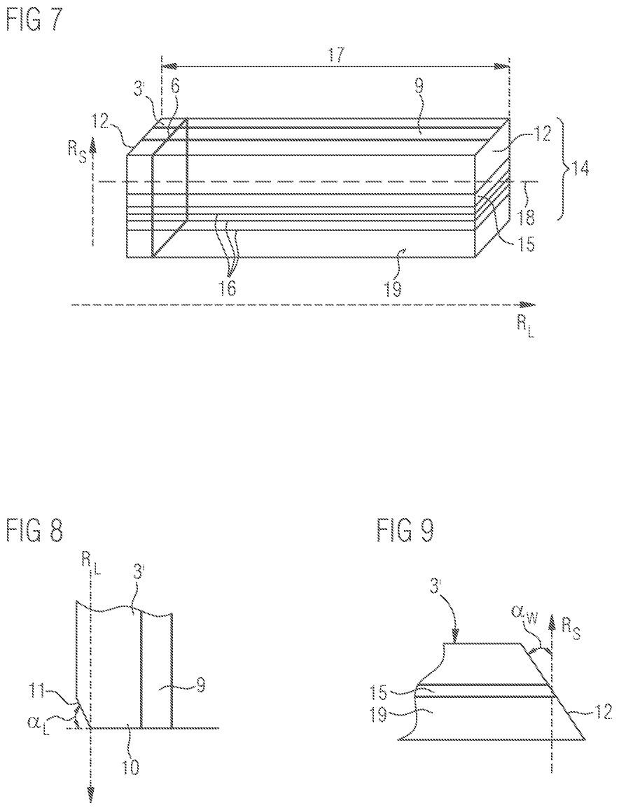

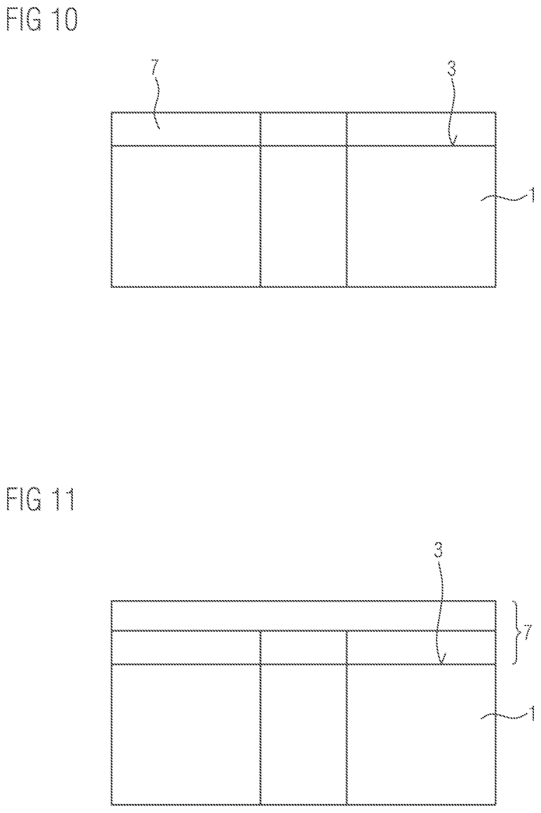

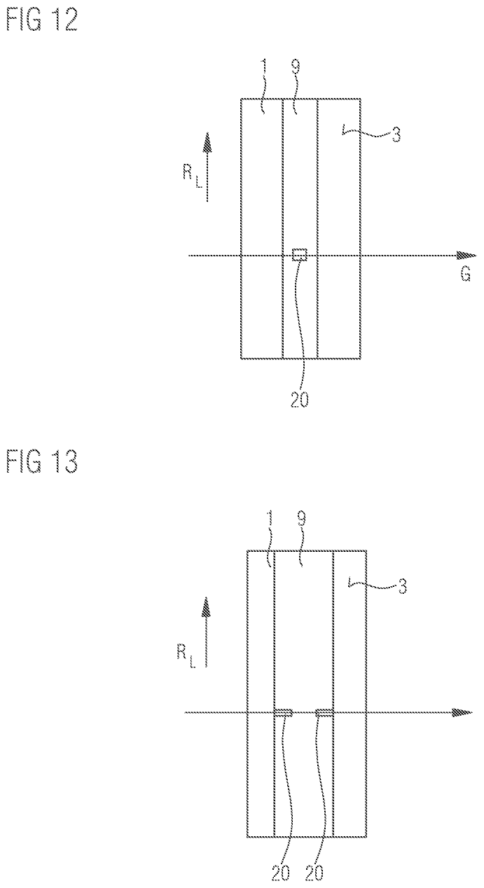

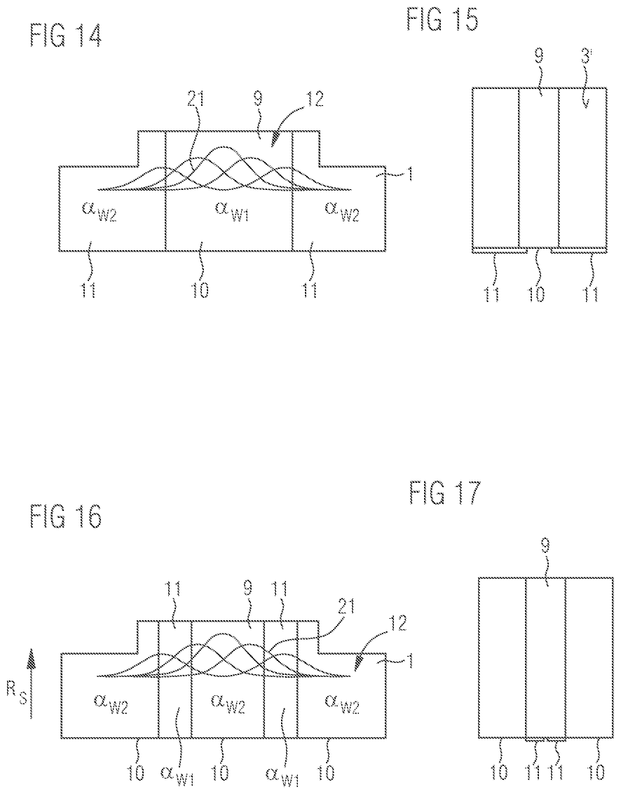

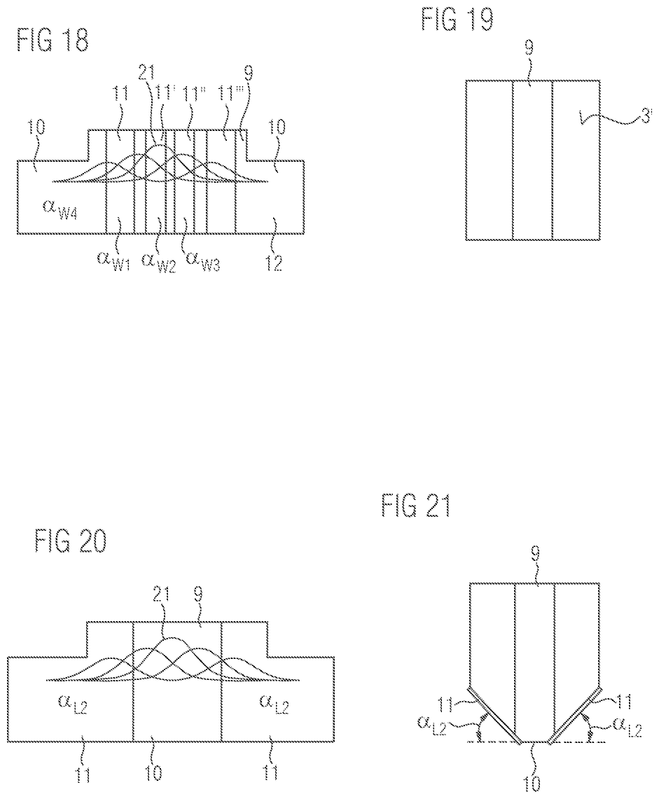

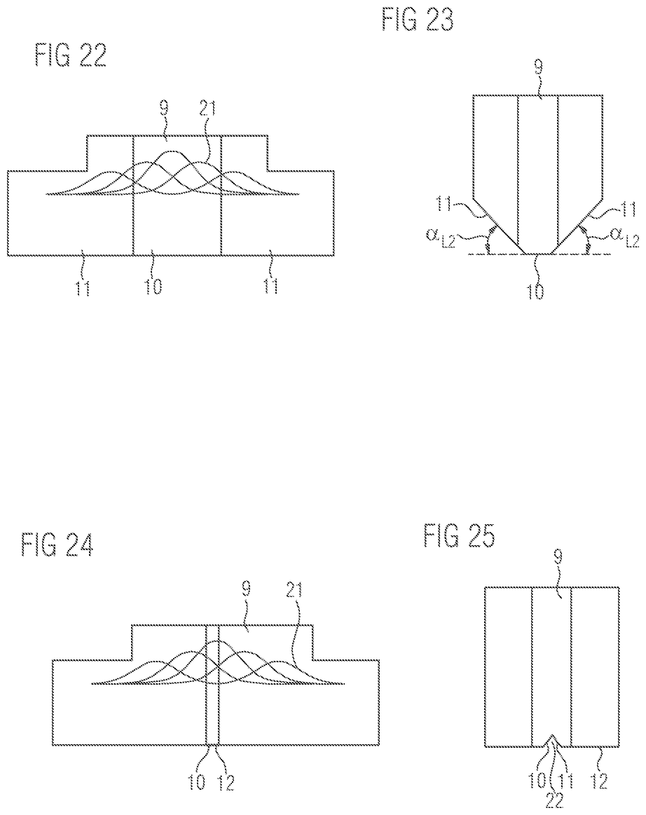

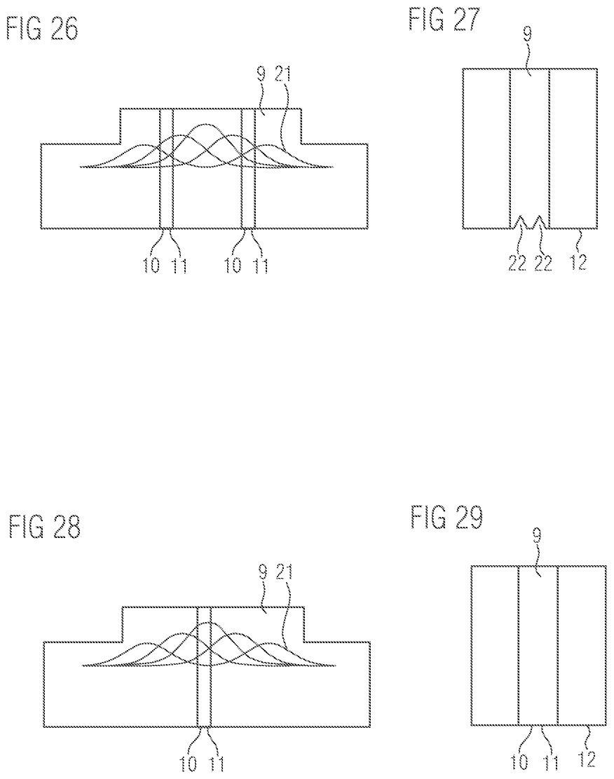

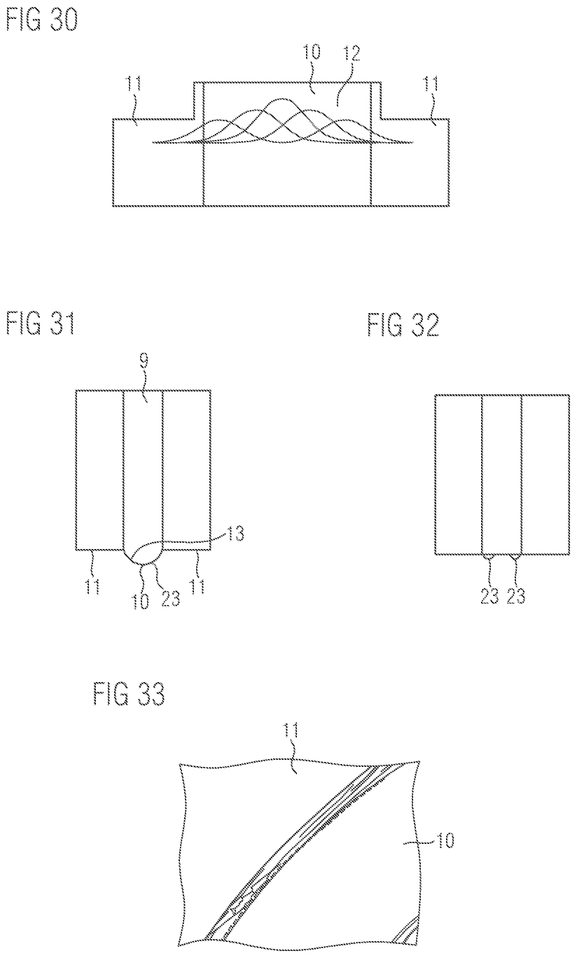

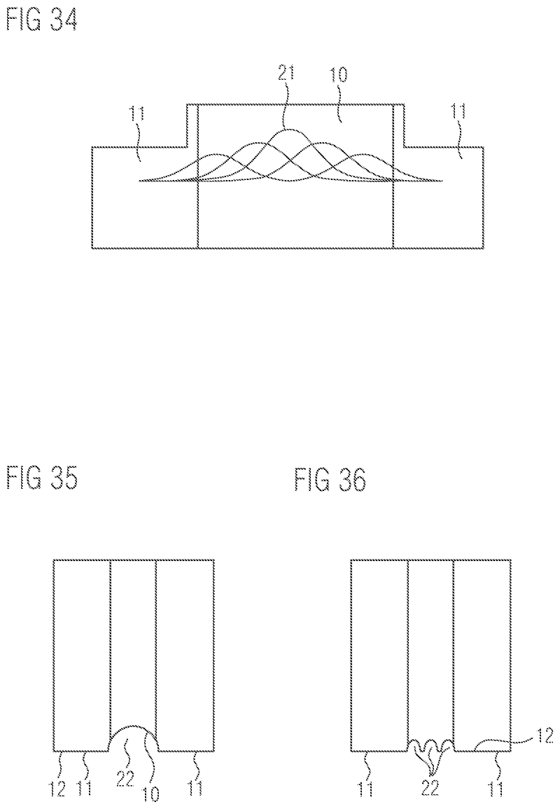

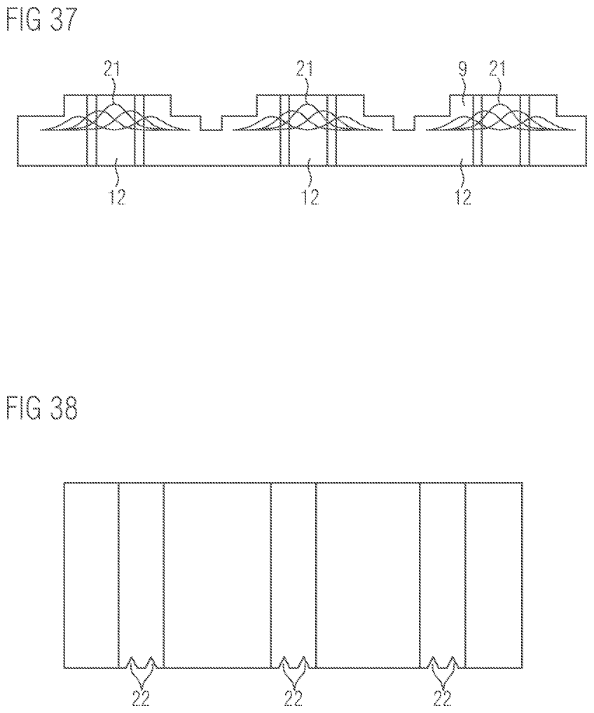

FIG. 6 shows a schematic top view of a facet 12 of an edge-emitting semiconductor laser diode as it can be produced using the method according to the exemplary embodiment of FIGS. 1 to 5.

The edge-emitting semiconductor laser diode according to the exemplary embodiment of FIG. 6 has a facet 12 with a first partial surface 10 and two second partial surfaces 11, wherein the first partial surface 10 is arranged between the second partial surfaces 11. In the present case, the first partial surface 10 has a lower roughness than the two second partial surfaces 11, which have the same roughness in the present case.

In the present case, the first partial surface 10 covers a radiation exit region 13 of the facet, from which electromagnetic laser radiation generated during operation emerges from the semiconductor laser diode. In particular, the edge-emitting semiconductor laser diode according to the exemplary embodiment of FIG. 6 has a ridge waveguide 9, under which the radiation exit region 13 of the facet 12 is arranged.

The schematic diagrams in FIGS. 7 and 9 are used to explain the terms “vertical main surface 6”, “longitudinal direction R_{L}”, “stacking direction R_{S}” and “vertical angle α_{W}” and “lateral angle α_{L}” in more detail.

The semiconductor laser diode according to FIG. 7 has an epitaxial semiconductor layer stack 14 with an active zone 15. The epitaxial semiconductor layer stack 14 has a plurality of epitaxial semiconductor layers 16 which are stacked on top of each other in a stacking direction R_{S}.

The epitaxial semiconductor layer stack 14 is delimited by two facets 12, which form a resonator 17. A longitudinal direction R_{L} extends from one facet 12 to the opposite other facet 12 parallel to an optical axis 18 of the resonator 17.

The two facets 12 are further connected to each other by side surfaces 19 of the epitaxial semiconductor layer stack 16, which extend parallel to the longitudinal direction R_{L}. Furthermore, a ridge waveguide 9 extends along the longitudinal direction R_{L} between the two facets 12.

A vertical main surface 6 of the epitaxial semiconductor layer stack runs parallel to the stacking direction R_{S} and is perpendicular to the longitudinal direction R_{L}.

FIG. 8 shows a top view of a main surface 3′ of the epitaxial semiconductor layer stack 14 with the ridge waveguide 9. A second partial surface 11 of the facet 12 encloses a lateral angle α_{L} with the vertical main surface 6, while a first partial surface 10 of the facet 12 runs parallel to the vertical main surface 6.

FIG. 9 shows a top view of a side surface 19 of the epitaxial semiconductor layer stack 14, with a second partial surface 11 of the facet 12 forming a vertical angle α_{W} with the vertical main surface 6.

In the method according to the exemplary embodiment of FIG. 10, a mask 7 is applied to a main surface 3 of the epitaxial semiconductor layer sequence 1. In the present case, the mask 7 comprises two different mask layers 7′, 7″, which are arranged laterally next to one another and cover different regions of the main surface 3 of the epitaxial semiconductor layer sequence 1. In other words, the mask is structured. The mask layers 7′, 7″ are formed, for example, from different materials. For example, metals, oxides, or photoresist are suitable materials for the mask layers 7′, 7″. The two mask layers 7′, 7″ of the mask 7 can have different selectivities for a subsequent dry etching process.

In a subsequent step, which is not shown here, a plurality of trenches 4 is generated in the epitaxial semiconductor layer sequence 3 using a dry etching process such as plasma etching. Due to the structuring of the mask 7, trenches 4 with side surfaces 5 with different lateral angles di are formed with a vertical main surface 6 in the dry etching process.

In a subsequent step, the areas of the side surfaces 5 that include different lateral angles α_{L} with the vertical main surface 6 are wet chemically etched so that regions that include a smaller lateral angle α_{L} with the vertical main surface 6 have a lower roughness, as they are smoothed more than regions that include a larger lateral angle α_{L} with the vertical main surface 6, especially if the epitaxial semiconductor layer sequence 1 is based on GaN. The reason for this is the deviation of the tilted plane from an m-plane of the GaN crystal.

For example, areas of the side surface 5 that are strongly smoothed have lateral angles α_{L} with the vertical main surface 6 not greater than +/−6°, while areas that are poorly smoothed include a lateral angle α_{L} of at least +/−8°, preferably of at least +/−10° with the vertical main surface 6.

In the method according to the exemplary embodiment of FIG. 11, a mask 7 with two different mask layers 7′, 7″, which have different selectivities for a dry etching process, is used as in the method according to the exemplary embodiment of FIG. 10. However, in the present method, the two mask layers 7′, 7″ are not only arranged laterally next to each other, but also on top of each other in a stacking direction R_{S} of the semiconductor layer sequence 1. Thus, in the dry etching process, trenches 4 are generated whose side surfaces 5 have partial surfaces 10, 11 that enclose different vertical angles αW with a vertical main surface 6.

In this exemplary embodiment, the side surfaces 5 of the trenches 4 are also smoothed by a wet chemical method in which partial surfaces 10, 11, which include a vertical angle α_{W} not greater than +/−6° with the vertical main surface 6, are smoothed strongly and partial surfaces 10, 11, which include a vertical angle α_{W} greater than +/−8°, preferably greater than +/−10° with the vertical main surface 6, are smoothed weakly or not at all.

In the method according to the exemplary embodiment of FIGS. 12 and 13, a plurality of structural elements 20 are first introduced into a main surface 3 of the epitaxial semiconductor layer sequence 1, for example by plasma etching (FIG. 12). For reasons of clarity, FIGS. 12 and 13 show only a section of the epitaxial semiconductor layer sequence 1, which later forms two semiconductor laser diodes. Therefore, FIG. 12, in particular, shows a single structural element.

For example, the structural elements 20 are arranged along a straight line G, which is perpendicular to a stacking direction R_{S} of the epitaxial semiconductor layer sequence 1 and to a longitudinal direction R_{L}.

In a next step, the facets 12 are generated by singulating the edge-emitting semiconductor laser diodes along separation lines that run through the cut-outs 20 by scribing and breaking.

The semiconductor laser diode according to the exemplary embodiment of FIGS. 14 and 15 has a facet 12 with a first partial surface 10 and two second partial surfaces 12. The first partial surface 10 is arranged between the two second partial surfaces 12 and covers a radiation exit region 13 of the facet 12. In the present case, the first partial surface 10 has a smaller first vertical angle α_{W1} with a vertical main surface 6 than the two second partial surfaces 12, which each include a larger second vertical angle α_{W2} with the vertical main surface 6.

Furthermore, the first partial surface 10 has a lower roughness and thus a greater reflectivity for the electromagnetic radiation generated in an active zone 15 of the edge-emitting semiconductor laser diode. Therefore, modes 21 of an electromagnetic laser radiation generated within the active zone 15 in a resonator 17 of the semiconductor laser diode and impinging on the second partial surface 11 are attenuated, while modes 21 of the electromagnetic laser radiation impinging on the first partial surface 10 of the facet 12 are amplified.

Furthermore, the semiconductor laser diode according to the exemplary embodiment in FIGS. 14 and 15 has a ridge waveguide 9. The second partial surfaces 11 also partially cover the ridge waveguide 9 at the facet 12. The first partial surface 10 is arranged completely in the region of the ridge waveguide 9.

In contrast to the semiconductor laser diode according to the exemplary embodiment of FIGS. 16 and 17, the semiconductor laser diode according to the exemplary embodiment of FIGS. 14 and 15 has a facet 12 which has three first partial surfaces 10 and two second partial surfaces 11, the second partial surfaces 11 being arranged between the first partial surfaces 10. The first partial surfaces 10 have a lower roughness and thus a higher reflectivity for electromagnetic laser radiation generated in a resonator 17 than the second partial surfaces 11.

The two second partial surfaces 11 are in the present case strip-shaped and extend along a stacking direction R_{S} of the epitaxial semiconductor layer stack 14. Furthermore, the two second partial surfaces 11 lie completely below a ridge waveguide 9.

The semiconductor laser diode according to the exemplary embodiment of FIGS. 18 and 19 has several partial surfaces 10, 11, 11′, 11″, 11′″, which have different vertical angles α_{W1}, α_{W2}, α_{W3}, α_{W4} with a vertical main surface 6 of an epitaxial semiconductor layer stack 14. Furthermore, the different partial surfaces 10, 11, 11′, 11″, 11′″ have different roughnesses depending on the vertical angle α_{W1}, α_{W2}, α_{W3}, α_{W4}.

In contrast to the semiconductor laser diodes described so far, the semiconductor laser diode according to the exemplary embodiment of FIGS. 20 and 21 has a first partial surface 10 and two second partial surfaces 11, the second partial surfaces 11 each forming a second lateral angle α_{L2} with a vertical main surface 6 of the epitaxial semiconductor layer stack 14. In contrast, the first partial surface 10 extends parallel to the vertical main surface 6. In addition, the first partial surface 10 is arranged between the second partial surfaces 11. Furthermore, the first partial surface 10 is smoothed with respect to the two second partial surfaces 11, so that the first partial surface 10 has a lower roughness than the two second partial surfaces 11.

In the semiconductor laser diode according to the exemplary embodiment of FIGS. 22 and 23, the second partial surfaces 11 are smoothed by a wet chemical method compared to the exemplary embodiment of FIGS. 20 and 21.

The semiconductor laser diode according to the exemplary embodiment of FIGS. 24 and 25 has a first partial surface 10 and a second partial surface 11, wherein the first partial surface 10 forms a first lateral angle du with a vertical main surface 6 and the second partial surface 11 forms a second lateral angle as. The first partial surface 10 and the second partial surface 11 are arranged directly adjacent to each other in a radiation exit region 13 of the facet 12 and form a cut-out 22 in the facet 12. The cut-out 22 has a triangular cross-sectional area in plan view of the semiconductor laser diode.

The semiconductor laser diode according to the exemplary embodiment of FIGS. 26 and 27, in contrast to the semiconductor laser diode according to the exemplary embodiment of FIGS. 24 and 25, has two cut-outs 22 in a radiation exit region 13 of the facet 12.

In contrast to the semiconductor laser diode of FIGS. 24 and 25, the semiconductor laser diode according to the exemplary embodiment of FIGS. 28 and 29 has a protrusion 23 on the facet 12 in the radiation exit region 13. The protrusion 23 is formed by a first partial surface and a second partial surface 11 on the facet 12, the first partial surface forming a first lateral angle and the second partial surface forming a second lateral angle with a vertical main surface.

In contrast to the semiconductor laser diode according to the exemplary embodiment of FIGS. 30 and 31, the semiconductor laser diode according to the exemplary embodiment of FIGS. 28 and 29 has a protrusion 23 which has a semicircular cross-sectional area in plan view.

In contrast to the semiconductor laser diode according to the exemplary embodiment of FIGS. 30 and 31, the semiconductor laser diode according to the exemplary embodiment of FIG. 32 has two protrusions 23 arranged next to each other, each of which has a semicircular cross-sectional area in plan view. The two protrusions 23 are arranged in a radiation exit region 13 of the facet 12.

FIG. 33 shows an exemplary scanning electron microscope image of an outer surface of a round protrusion 23, as shown schematically in FIGS. 31 and 32, for example. The depicted epitaxial semiconductor layer stack 14 is based on a nitride compound semiconductor material. In particular, the epitaxial semiconductor layer stack 14 is formed of gallium nitride.

Rounded protrusions 23 or cut-outs 22 in a facet 12 of the epitaxial semiconductor layer stack 14 can be generated by circular structuring (concave or convex) during plasma etching. In particular, a smooth and vertical first partial surface 10 is generated at an apex of the circular arc during a subsequent wet chemical etching when the circular arc coincides with the m-face of the gallium nitride crystal. In addition, a very rough second partial surface 12 is generated at the facet.

In contrast to the semiconductor laser diode according to the exemplary embodiment of FIGS. 34 and 35, the semiconductor laser diode according to the exemplary embodiment of FIGS. 30 and 31 has a facet 12 with a cut-out 22, which has a semicircular base area in plan view. Second partial surfaces 11, which have a comparatively high roughness, are arranged at the side of the cut-out 22.

The semiconductor laser diode according to the exemplary embodiment of FIG. 36 has a facet 12 with three cut-outs 22, each of which has a semicircular base area when viewed from above. The cut-outs 22 are arranged next to each other in a radiation exit region 13.

The array according to the exemplary embodiment of FIGS. 37 and 38 comprises several edge-emitting semiconductor laser diodes, as already described. In particular, each semiconductor laser diode has two cut-outs 22 with a base area that is triangular in plan view in a radiation exit region 13, which are arranged next to each other.

The invention is not limited to the description based on the embodiments. Rather, the invention includes any new feature as well as any combination of features, which includes in particular any combination of features in the patent claims, even if this feature or combination itself is not explicitly stated in the patent claims or embodiments.

1. An edge emitting semiconductor laser diode comprising:
an epitaxial semiconductor layer stack comprising an active zone, in which electromagnetic radiation is generated during operation, wherein
the epitaxial semiconductor layer stack has at least one facet, which laterally delimits the epitaxial semiconductor layer stack,
the facet has at least a first partial surface and at least a second partial surface, which have different reflectivities from one another for the electromagnetic radiation generated in the active zone, and
the first partial surface amplifies a desired mode of the electromagnetic laser radiation, and the second partial surface at least attenuates undesired modes of the electromagnetic laser radiation.

2. The edge emitting semiconductor laser diode according to claim 1,
wherein the electromagnetic radiation generated in the active zone is formed in a resonator into electromagnetic laser radiation comprising a plurality of modes.

3. The edge-emitting semiconductor laser diode according to claim 1, wherein the first partial surface and the second partial surface have different roughnesses.

4. The edge emitting semiconductor laser diode according to claim 1, wherein
the first partial surface is formed tilted by a first vertical angle relative to a vertical main surface of the epitaxial semiconductor layer stack, wherein the vertical main surface is perpendicular to a longitudinal direction, and/or
the second partial surface is tilted by a second vertical angle relative to the vertical main surface of the epitaxial semiconductor layer stack.

5. The edge emitting semiconductor laser diode according to claim 1, wherein
the first partial surface is tilted by a first lateral angle relative to the vertical main surface of the epitaxial semiconductor layer stack, and/or
the second partial surface is tilted by a second lateral angle relative to the vertical main surface of the epitaxial semiconductor layer stack.

6. The edge-emitting semiconductor laser diode according to claim 1, wherein
the first partial surface covers a radiation exit region of the facet.

7. The edge emitting semiconductor laser diode according to claim 1, wherein
the first partial surface covers a radiation exit region of the facet, and
the first partial surface is arranged between two second partial surfaces, which have a lower reflectivity for the electromagnetic radiation of the active zone than the first partial surface.

8. The edge emitting semiconductor laser diode according to claim 1, which has a ridge waveguide.

9. The edge emitting semiconductor laser diode according to claim 1, wherein the facet has further partial surfaces with at least partially different reflectivities for the electromagnetic radiation generated in the active zone.

10. The edge-emitting semiconductor laser diode according to claim 1, wherein the facet has a plurality of partial surfaces each of which is tilted by a lateral angle relative to the vertical main surface of the epitaxial semiconductor layer stack and forms at least one cut-out and/or at least one protrusion in the facet.

11. An array comprising at least two edge-emitting semiconductor laser diodes according to claim 1.

12. A method of manufacturing a plurality of edge-emitting semiconductor laser diodes comprising:
providing an epitaxial semiconductor layer sequence with an active region, which generates electromagnetic radiation during operation,
generating one or more trenches in the epitaxial semiconductor layer sequence, and
generating at least a first partial surface and at least a second partial surface on a side surface of the trench,
wherein
the first partial surface and the second partial surface have different reflectivities from one another for the electromagnetic radiation generated in the active region, and
the first partial surface amplifies a desired mode of the electromagnetic laser radiation, and the second partial surface at least attenuates undesired modes of the electromagnetic laser radiation.

13. The method according to claim 12, wherein
the trenches are generated by a dry etching process so that the side surfaces of the trenches have a vertical angle tilted to a vertical main surface of the epitaxial semiconductor layer sequence, the vertical main surface being perpendicular to a longitudinal direction, and
the first partial surface or the second partial surface is generated by a wet chemical method using a mask, wherein the first partial surface and the second partial surface have different roughnesses.

14. The method according to claim 13,
wherein the partial surface generated by the wet chemical method has a lower roughness than the other partial surface.

15. The method according to claim 12,
wherein the trenches are generated with a dry etching process using a mask, so that the first partial surface encloses a first vertical angle with the vertical main surface and/or the second partial surface encloses a second vertical angle with the vertical main surface.

16. The method according to 12,
in which the trenches are generated with a dry etching process using at least one mask, so that the first partial surface encloses a first lateral angle with the vertical main surface and/or the second partial surface encloses a second lateral angle with the vertical main surface.

17. The method according to claim 15, wherein the mask has at least two mask layers, which have different selectivities for the dry etching process.

18. A method of manufacturing a plurality of edge-emitting semiconductor laser diodes comprising:
providing an epitaxial semiconductor layer sequence with an active region, which generates electromagnetic radiation during operation,
generating a plurality of structural elements in the epitaxial semiconductor layer sequence, wherein a side surface of a structural element at least partially forms a first partial surface of a facet of a finished semiconductor laser diode,
singulating the semiconductor layer sequence to form a plurality of edge-emitting semiconductor laser diodes, so that at least a second partial surface of the facet of the finished semiconductor laser diode is formed,
wherein
the first partial surface and the second partial surface have different reflectivities from one another for the electromagnetic radiation generated in the active region, and
the first partial surface amplifies a desired mode of the electromagnetic laser radiation, and the second partial surface at least attenuates undesired modes of the electromagnetic laser radiation.

19. The method according to claim 18, wherein the first partial surface has a greater roughness than the second partial surface.
